(19) United States
(12) Patent Application Publication
(10) Pub. No.: US 2026/0092982 A1
(43) Pub. Date: Apr. 2, 2026

(54) AN APPARATUS FOR DETECTING DEFECTS OF A BATTERY CELL AND A METHOD FOR DETECTING DEFECTS OF A BATTERY CELL

(71) Applicant: LG ENERGY SOLUTION, LTD., Seoul (KR)

(72) Inventors: Jong Cheol LEE, Daejeon (KR); Bong Keun KWON, Daejeon (KR); Jaehwan LIM, Daejeon (KR); Jinwoong KIM, Daejeon (KR)

(21) Appl. No.: 19/120,211

(22) PCT Filed: Dec. 19, 2023
(86) PCT No.: PCT/KR2023/021005

§ 371 Date: Apr. 10, 2025

(30) Foreign Application Priority Data
Dec. 21, 2022 (KR) 10-2022-0180417

(51) Int. Cl. G01R 31/392; G01R 31/3832; G01R 33/00; G01R 33/02

(52) U.S. Cl. CPC G01R 31/392; G01R 31/3832; G01R 33/0005; G01R 33/0206

(57) ABSTRACT

An apparatus for detecting a defect in a battery cell according to an embodiment of the present disclosure includes a magnetic field measuring section; a support section supporting the magnetic field measuring section; and a mounting section for placing the battery cell, wherein the magnetic field measuring section comprises a first measuring member configured to scan a first side of the battery cell, a second measuring member configured to scan a second side of the battery cell opposite to the first side, and a third measuring member coupled between the first measuring member and the second measuring member, and wherein the first measuring member, the second measuring member and the third measuring member are connected together.

### CROSS CITATION WITH RELATED APPLICATION(S)

This application is a National Phase entry pursuant to 35 U.S.C. § 371 of International Application No. PCT/KR2023/021005 filed on Dec. 19, 2023, which claims priority to and the benefit of Korean Patent Application No. KR 10-2022-0180417, filed on Dec. 21, 2022. The contents of the above-identified applications are herein incorporated by reference in their entireties.

### TECHNICAL FIELD

The present disclosure relates to an apparatus for detecting defects of a battery cell and a method for detecting defects of a battery cell, and more specifically, to an apparatus for detecting defects of a battery cell that detects an abnormal current in a battery cell, and a defective battery cell, and/or detects a defective portion by applying a 3D magnetic field scanning sensor and determining an abnormal current, and a detecting method therefor.

### BACKGROUND

X-ray CT, which is a conventional non-contact, non-destructive analysis method for battery cells, requires a long analysis time, thus making real-time analysis of various defect causes impossible. Further, visual detection such as X-ray CT is not effective for verifying battery cell deterioration or defects (lithium deposition, tab breakage, etc.), and thus analysis by disassembly is required. In order to solve defects of such X-ray CT analysis, studies have been conducted to analyze defects through visualization of the current distribution inside the battery cell, however, in the measurement of induced magnetic fields through MRI guidance, it was impossible for electromagnetic waves to penetrate battery cells, and it was also difficult to obtain high resolution due to the ferromagnetic material contained in the battery cells.

Therefore, it is necessary to develop diagnostic technology and testing methods for cell deterioration and defects through non-destructive analysis. As a way to detect such changes, research has recently been conducted to introduce technology using magnetic field imaging (MFI) to detect defects through changes in the magnetic field formed during charging and discharging of battery cells.

FIG. 1 shows an apparatus 1 for detecting defects of a battery cell according to the prior art. Imaging of current flow through MFI measurement is performed on the cross section of the battery cell. In other words, the magnetic field is measured while flowing current through the battery cell, and then the current value is calculated using the current-magnetic field relationship (Biot-Savart Law) and imaged. However, according to this prior art, the measurement unit exists only on the top surface, so that only 2D cross-sectional measurement of the battery cell is possible. Further, only magnetic field detection on the surface of the battery cell (i.e., the surface facing the magnetic field detection apparatus) is possible, and detection of magnetic fields on the side surface or bottom surface of the battery cell is impossible. The apparatus for detecting defects of a battery cell according to the prior art performs magnetic field measurements limited to a 2D cross section and only the surface current is observed, and so it is limited in detecting disconnection/foreign substances inside the cell.

The background description provided herein is for the purpose of generally presenting context of the disclosure. Unless otherwise indicated herein, the materials described in this section are not prior art to the claims in this application and are not admitted to be prior art, or suggestions of the prior art, by inclusion in this section.

### SUMMARY

The present disclosure provides an apparatus for detecting defects of a battery cell and a method for detecting defects of a battery cell. The present disclosure also provides a technique for sensing abnormal currents in a battery cell particularly by implementing in 3D when applying a magnetic field imaging technique. The present disclosure detects defects of a battery cell more effectively, that is, more quickly and more accurately, using a more efficient method for calculating abnormal current in a battery cell and determining an abnormal current.

However, the technical problems to be solved by embodiments of the present disclosure are not limited to the above-described problems, and can be variously expanded within the scope of the technical idea included in the present disclosure.

An apparatus for detecting a defect in a battery cell, may include: a magnetic field measuring section; a support section supporting the magnetic field measuring section; and a mounting section for placing the battery cell, wherein the magnetic field measuring section may include a first measuring member configured to scan a first side of the battery cell, a second measuring member configured to scan a second side of the battery cell opposite to the first side, and a third measuring member coupled between the first measuring member and the second measuring member, and wherein the first measuring member, the second measuring member and the third measuring member may be connected together.

In certain embodiments of an apparatus for detecting a defect in a battery cell, the magnetic field measuring section may simultaneously scan a top surface, a bottom surface, and a side surface of the battery cell.

In certain embodiments of an apparatus for detecting a defect in a battery cell, the third measuring member may connect a first end of the first measuring member to a first end of the second measuring member.

In certain embodiments of an apparatus for detecting a defect in a battery cell, the third measuring member may be a plurality of third measuring members, wherein a primary measuring member of the plurality of third measuring members may connect a first end of the first measuring member to a first end of the second measuring member, and a secondary measuring member of the plurality of third measuring members may connect a second end of the first measuring member to a second end of the second measuring member.

In certain embodiments of an apparatus for detecting a defect in a battery cell, the mounting section may include a base and a support member, wherein the support member may have a plate shape for placing the battery cell, and the support member may be spaced apart at a prescribed distance upward from the base, and the second measuring member may disposed below the support member.

In certain embodiments of an apparatus for detecting a defect in a battery cell, the support member may have a low magnetic permeability (u) so that an influence of the support member on magnetic field scanning of the second measuring member is minimized.

In certain embodiments of an apparatus for detecting a defect in a battery cell, a processing unit may be configured to convert measured magnetic field data to determine the defect in the battery cell or a defective portion of the battery cell.

In certain embodiments of an apparatus for detecting a defect in a battery cell, each of the first measuring member, the second measuring member and the third measuring member may have a bar or rod shape, and the magnetic field measuring section may be configured to scan the battery cell by moving in a longitudinal direction of the battery cell.

In certain embodiments of an apparatus for detecting a defect in a battery cell, the first measuring member, the second measuring member and the third measuring member may each individually generate a magnetic field data.

In certain embodiments of an apparatus for detecting a defect in a battery cell, a three-dimensional magnetic field vector value may be generated from magnetic field data individually generated from each of the first measuring member, the second measuring member, and the third measuring member.

In certain embodiments of an apparatus for detecting a defect in a battery cell, the magnetic field data may be a magnetic field image (MFI).

In certain embodiments of an apparatus for detecting a defect in a battery cell, the defect in the battery cell may include at least one of: a folded portion of an electrode plate of the battery cell, a disconnected portion of an electrode plate, an electrode active material unevenly applied to a coated portion of an electrode plate, a disconnected portion of an electrode lead, a disconnected portion of an electrode tab, or a misalignment of stacked electrode plates.

A method for detecting defects of a battery cell, the method may include the steps of: receiving magnetic field data measured by a magnetic field measuring section; deriving a three-dimensional magnetic field vector value for each of a plurality of sub-regions of the battery cell from the received magnetic field data; converting each of the derived three-dimensional magnetic field vector values into an induced current vector value for a sub-region of the plurality of sub-regions of the battery cell; and detecting a defect in the battery cell or a defective portion of the battery cell by determining whether a particular induced current vector value for a sub-region of the plurality of sub-regions of the battery cell corresponds to a current value in a normal range by comparing the particular induced current vector value for the sub-region of the plurality of sub-regions of the battery cell with a prescribed current vector threshold.

In certain embodiments of a method for detecting defects of a battery cell, converting a derived three-dimensional magnetic field vector value into an induced current vector value for a sub-region of the plurality of sub-regions of the battery cell may include multiplying by a correction coefficient.

In certain embodiments of a method for detecting defects of a battery cell, determining whether a particular induced current vector value for a sub-region of the plurality of sub-regions of the battery cell corresponds to a current value in a normal range may include determining if the particular induced current vector value for the sub-region of the plurality of sub-regions of the battery cell is larger than a prescribed upper limit current vector threshold or determining if the particular induced current vector value for the sub-region of the plurality of sub-regions of the battery cell is smaller than a prescribed lower limit current vector threshold.

According to the present disclosure, when applying magnetic field imaging technology to detect defects of a battery cell, it is especially possible to inspect battery cells more precisely from multiple perspectives, thereby making it possible to ensure reliability in the quality of the produced battery cells.

In addition, highly reliable preliminary inspection is possible at the battery cell level, and therefore, when inspecting a battery module or battery pack, it is also possible to solve the inefficiency problem of discarding the entire battery module or battery pack due to one defective cell.

Effects obtainable from the present disclosure are not limited to the effects mentioned above, and additional other effects not mentioned herein will be clearly understood from the description of the appended claims by those skilled in the art.

### BRIEF DESCRIPTION OF THE DRAWINGS

FIG. 1 shows an apparatus for detecting defects of a battery cell according to the prior art.

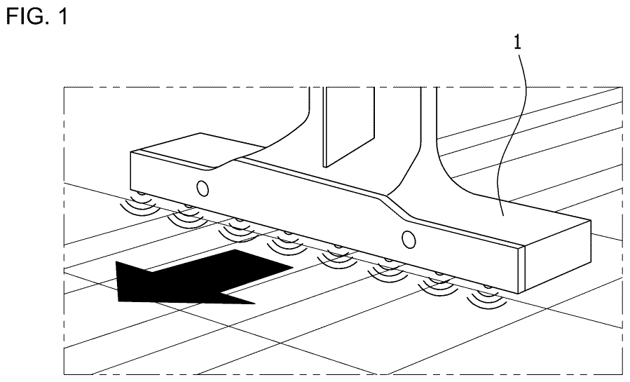

FIG. 2 is a perspective view which schematically shows an apparatus for detecting defects of a battery cell according to an embodiment of the present disclosure.

FIG. 3 is a front view of an apparatus for detecting defects of a battery cell of FIG. 2.

FIG. 4 is an example of a magnetic field image generated by the MFI method.

FIG. 5 shows an example of the final current vector value.

FIG. 6 shows an example of a type of defects in a battery cell.

The accompanying drawings illustrate various embodiments of the present disclosure and together with the foregoing disclosure, serve to provide further understanding of the technical features of the present disclosure, and thus, the present disclosure is not construed as being limited to the drawings.

### DETAILED DESCRIPTION

Hereinafter, embodiments disclosed in the present specification will be described in detail with reference to the accompanying drawings, however, identical or similar elements are considered to have identical reference numerals regardless of drawing, and a redundant description thereof will be omitted.

The suffixes “member” and/or “part” of elements used in the description below are assigned or used only in consideration of the ease of description of the specification, and the suffixes themselves do not have meanings or roles distinguished from each other.

In the following description of the present disclosure, a detailed description of known functions and configurations incorporated herein will be omitted when it may make the subject matter of the present disclosure unclear. In addition, the accompanying drawings ease the understanding of the embodiments disclosed in the present specification, however, the technical principles disclosed herein are not limited by the accompanying drawings and should be construed as including all changes, equivalents and substitutes included in the spirit and scope of the present disclosure.

In this specification, terms such as “include” or “have” are intended to designate that the features, numbers, steps, operations, components, parts, or combinations thereof described in the specification exist, but it should be understood that this does not preclude the existence or addition of one or more other features, numbers, steps, operations, components, parts, or combinations thereof.

Now, an apparatus 100 for detecting defects of a battery cell according to an embodiment of the present disclosure will be described.

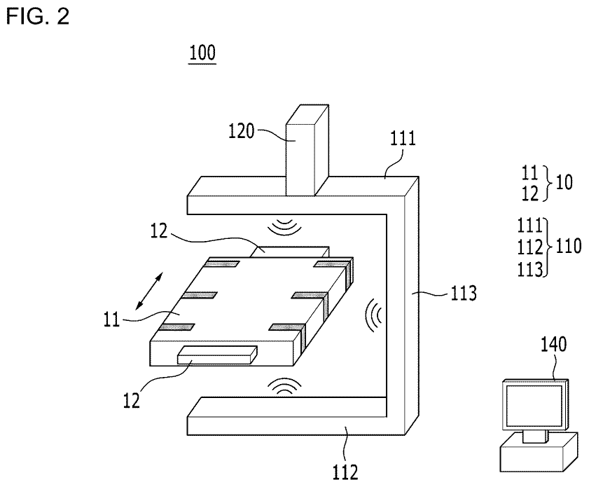

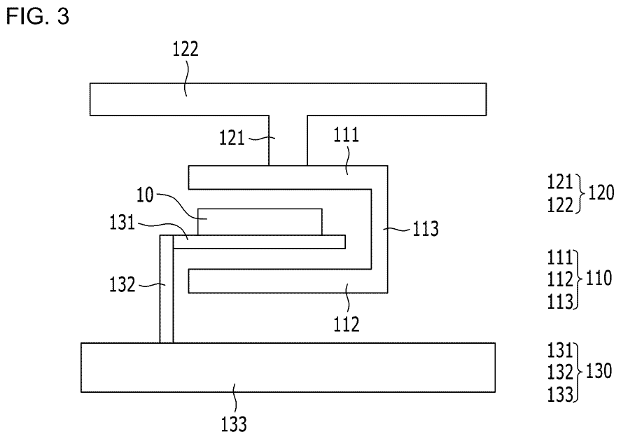

FIG. 2 is a perspective view which schematically shows an apparatus 100 for detecting defects of a battery cell according to an embodiment of the present disclosure. FIG. 3 is a front view of an apparatus 100 for detecting defects of a battery cell of FIG. 2.

The apparatus 100 for detecting defects of a battery cell according to an embodiment of the present disclosure broadly includes: a magnetic field measuring section 110, a support section 120 to which the magnetic field measuring section 110 is connected to fix and support the magnetic field measuring section 110, a mounting section 130 on which the battery cell 10 is placed, and a processing unit 140 and/or a storage unit 140.

The magnetic field measuring section 110 is disposed near the battery cell 10 and spaced away from the battery cell 10 by a prescribed distance. A current is applied to the battery cell 10, the current flows through the battery cell 10 between a positive electrode lead 12 and a negative lead 12 of the battery cell 10, and a magnetic field is induced therefrom. The magnetic field measuring section 110 measures the magnetic field derived from the current flowing through the battery cell 10. The main body 11 of the battery cell 10 may be scanned, and the main body 11, the positive electrode lead 12 and the negative electrode lead 12, and the positive electrode tab and the negative electrode tab may also be scanned as a whole.

In the apparatus 100 for detecting defects of a battery cell according to an embodiment of the present disclosure, the magnetic field measuring section 110 can scan the battery cell 10 in three dimensions at once. The magnetic field measuring section 110 may have, for example, a [symbol] /“U” shape or a square shape. More specifically, the magnetic field measuring section 110 includes a first measuring member 111 that scans one side of the battery cell 10, a second measuring member 112 that scans the other side opposite to one side of the battery cell 10, and one or two third measuring members 113 coupled between the first measuring member 111 and the second measuring member 112.

The first measuring member 111 and the second measuring member 112 may be arranged in parallel to each other. Further, one third measuring member 113 may be coupled between one end of the first measuring member 111 and one end of the second measuring member 112. Thereby, the magnetic field measuring section 110 has a [symbol] /“U” shape. Alternatively, the two third measuring members 113 are each coupled between one end of the first measuring member 111 and one end of the second measuring member 112, or may be coupled between the other end of the first measuring member 111 and the other end of the second measuring member 112. Thereby, the magnetic field measuring section 110 may have a square shape.

Each of the first measuring member 111, the second measuring member 112, and the third measuring member 113 includes a scanner unit that scans a magnetic field on a surface facing the battery cell 10.

The first measuring member 111, the second measuring member 112, and the third measuring member 113 are integrated into one. More specifically, the first measuring member 111, the second measuring member 112, and the third measuring member 113 may be formed integrally, or may be fabricated separately and then coupled together. Further, each of the first measuring member 111, the second measuring member 112 and the third measuring member 113 may have a bar or rod shape. Alternatively, each of the first measuring member 111, the second measuring member 112 and the third measuring member 113 may have a plate shape. In the former case, the magnetic field measuring section 110 may scan the magnetic field of the battery cell 10 while moving along the longitudinal direction of the battery cell 10. In the latter case, if each of the first measuring member 111, the second measuring member 112 and the third measuring member 113 can cover the battery cell 10, the magnetic field of the battery cell 10 can be scanned at once without movement of the magnetic field measuring section 110.

For example, the first measuring member 111 may scan the top surface of the battery cell 10, and the second measuring member 112 may scan the bottom surface of the battery cell 10. Further, the third measuring member 113 may scan both sides or one side of the battery cell 10. However, the present disclosure is not limited to those set forth above, and when scanning with the battery cell 10 upright, various modifications and changes are possible, for example, the first measuring member 111 and the second measuring member 112 can each scan both sides of the battery cell 10, and the third measuring member 113 can scan the top surface or bottom surface of the battery cell 10.

In addition, the first measuring member 111, the second measuring member 112 and the third measuring member 113 simultaneously scan the battery cell 10, wherein the first measuring member 111, the second measuring member 112 and the third measuring member 113 individually generate magnetic field data from each of the battery cells 10. In regard to magnetic field data, refer to those described later.

A support section 120 is connected and fixed to the magnetic field measuring section 110 to support the magnetic field measuring section 110. In an exemplary embodiment of FIG. 3, the case where the support section 120 is connected to the first measuring member 111 is illustrated, but the present disclosure is not limited thereto, and the support section 120 may be connected to at least one of the first measuring member 111, the second measuring member 112 and the third measuring member 113.

When the magnetic field measuring section 110 scans the battery cell 10 while moving, the support section 120 may further include a driving member. The magnetic field measuring section 110 may scan the battery cell 10 while moving in the longitudinal direction by the driving member included in the support section 120.

The battery cell 10 is mounted on the mounting section 130 including the support member 131. The mounting unit 130 broadly includes a support member 131, a pillar member 132, and a base 133. The battery cell 10 is placed on the plate-shaped support member 131. The support member 131 may be located in the air at a prescribed distance upward from the bottom surface (e.g., base 133) by a pillar member 132. The second measuring member 112 of the magnetic field measuring section 110 is disposed on the bottom surface of the support member 131. Thereby, not only the first measuring member 111 may be disposed on one side of the battery cell 10, but also the second measuring member 112 opposite thereto may be disposed on the other side opposite to the one side of the battery cell 10.

Meanwhile, a support member 131 is located between the second measuring member 112 of the magnetic field measurement unit 110 and the battery cell 10. The support member 131 has a low magnetic permeability (u) so that the support member 131 has no influence on the magnetic field scanning of the second measuring member 112, or the influence is minimized.

Data containing the magnetic field value of the battery cell 10 measured by scanning in the magnetic field measuring section 110 (hereinafter referred to as “magnetic field data”) is transmitted to a processing unit 140 and/or a storage unit 140 by wire or wirelessly. The processing unit 140 and/or the storage unit 140 may be provided separately, or may be integrated into one device. The processing unit 140 and/or the storage unit 140 may be, for example, a computer, a notebook, or various control devices applicable to the implementation environment and corresponding process.

Magnetic field data scanned by the magnetic field measuring section 110 may be transmitted by wire through a data transmission line (not shown) provided on the support section 120 connected to the magnetic field measuring section 110. Alternatively, the magnetic field measuring section 110 or the support section 120 connected thereto may include a separate transceiver (not shown) to transmit the magnetic field data scanned by the magnetic field measuring section 110 wirelessly in real time (e.g., by repeating the method of scanning a certain portion of the battery cell 10 and transmitting magnetic field data) or after scanning is completed as a whole.

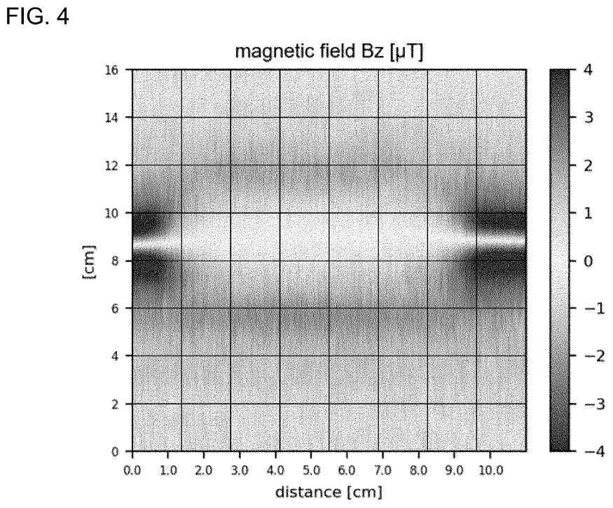

Further, the magnetic field data transmitted from the magnetic field measuring section 110 may be the magnetic field value itself, or may be a magnetic field image generated by the MFI method (e.g., see FIG. 4). Alternatively, the magnetic field data transmitted from the magnetic field measuring section 110 is the magnetic field value itself, and the processing unit 140 may generate a magnetic field image using the MFI method. The unit of magnetic field value is T by way of example.

In regard to the processing unit 140 and/or the storage unit 140, refer to a method for detecting defects of a battery cell to be described later.

Next, a method for detecting defects of a battery cell according to an embodiment of the present disclosure will be described. The method for detecting defects of a battery cell is performed in the processing unit 140 of the apparatus 100 for detecting defects of a battery cell. In addition, data can be transmitted/received, and stored in the storage unit 140. That is, the processing unit 140 may perform a method for detecting defects of a battery cell in conjunction with the storage unit 140.

First, a step (S110) of receiving magnetic field data from the magnetic field measuring section 110 in the processing unit 140 and/or the storage unit 140 is performed. In regard to magnetic field data transmission from the magnetic field measuring section 110, refer to the portion set forth above.

Further, a step (S120) of deriving magnetic field vector values for each of the plurality of sub-regions of the battery cell from the received magnetic field data is performed. The processing unit 140 generates three-dimensional magnetic field vector values B=(Bₓ, B_{y}, B_{z}) from the magnetic field data received from the magnetic field measuring section 110. The three-dimensional magnetic field vector values are magnetic field vector values at the x-axis position, y-axis position, and z-axis position of the battery cell 10. The region of the battery cell 10 can be divided into a plurality of sub-regions in three dimensions, and the magnetic field vector value B for each region can be generated. In the apparatus 100 for detecting defects of a battery cell of the present disclosure, since the magnetic field measuring section 110 scans the battery cell 10 in three dimensions, such a three-dimensional magnetic field vector value B can be generated from the magnetic field data received from the magnetic field measuring section 110.

In regard to the generation of the magnetic field vector value B, for example, each magnetic field image generated from the first measuring member 111, the second measuring member 112 and the third measuring member 113 of the magnetic field measuring section 110 is divided into a grid shape as shown in FIG. 4, and then a three-dimensional vector value B can be derived from the corresponding magnetic field image value for each region.

Further, for example, a three-dimensional magnetic field vector value B can be generated by a method of weighting, summing and correcting magnetic field data received from the first measuring member 111, the second measuring member 112 and the third measuring member 113 of the magnetic field measuring section 110. For example, since the first measuring member 111 and the second measuring member 112 are located on both surfaces of the battery cell 10 opposite to each other, a three-dimensional magnetic field vector value B can be derived by combining them.

However, the present disclosure is not limited to those set forth above, and any method that can generate a three-dimensional magnetic field vector value B=(Bₓ, B_{y}, B_{z}) is sufficient.

Next, a step (S130) of converting the derived magnetic field vector value into induced current data is performed. Since it is calculated from the magnetic field vector value, the induced current data becomes the induced current vector value (hereinafter referred to as “current vector value”).

Each of the three-dimensional magnetic field vector values B=(Bₓ, B_{y}, B_{z}) at the x-axis, y-axis, and z-axis positions of the battery cell 10 is converted into the current vector value I₀=(I₀ₓ, I_{0y}, I_{0z}). That is, the converted current value means the current value flowing at the corresponding x-axis, y-axis, and z-axis positions of the battery cell 10. The process of converting a magnetic field into a current follows the Biot-Savart Law of the following Mathematical Equation 1.

$$B = \frac{{μ}_{0}}{4 π} \int \frac{Id \vec{l} \times \hat{r}}{{r}^{2}} dr \qquad Mathematical Equation 1$$

wherein, B is the magnetic field, I is the current, μ₀ is the permeability in free space, and r is the diameter (i.e., the distance from the corresponding region of the battery cell 10 to the magnetic field meter 110).

In addition, when converting the corresponding magnetic field into current, the final current vector value/can be derived by multiplying the correction coefficient (α). This is a coefficient for correcting an error between the current value that actually flows in the relevant region of the battery cell 10 and the current value that is induced from the magnetic field due to the relevant device or surrounding environment, etc. If correction is not necessary, the correction coefficient can be set to α=1.

$$I = ( {I}_{x} , {I}_{y} , {I}_{z} ) α {I}_{0} \qquad Mathematical Equation 2$$

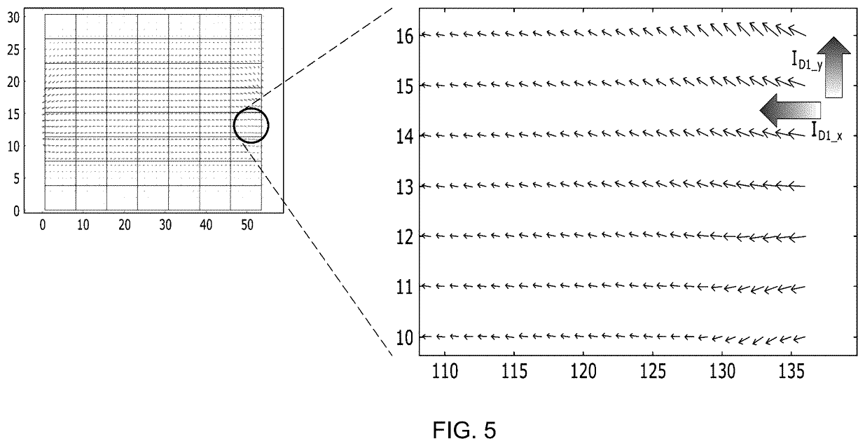

FIG. 5 shows an example of the final current vector value I.

In addition, the above process is performed from the magnetic field data transmitted from the first measuring member 111, the second measuring member 112 and the third measuring member 113, respectively, to derive I_{D1}, I_{D2}, I_{D3}. The I_{D1}, I_{D2}, I_{D3} mean I derived from the first measuring member 111, the second measuring member 112 and the third measuring member 113, respectively, in that order.

Next, a step (S140) of determining whether the induced current value corresponds to a current value in the normal range is performed. By comparing the derived induced current vector value with the current vector threshold, the presence or absence of an abnormal current can be determined.

The presence or absence of an abnormal current is determined by comparing respective I_{D1}, I_{D2}, I_{D3} with the current threshold value I_{TH} of a normal cell. That is, if it exceeds the current threshold I_{TH} of a normal cell, it can be determined as a current abnormality. In addition, the current threshold of the normal cell may be set to an upper current threshold I_{TH-high} and/or a lower current threshold I_{TH-low}, respectively. In this case, if I is larger than the upper current threshold I_{TH-high} or smaller than the lower current threshold I_{TH-low}, it can be determined as a current abnormality. Further, respective I_{D1}, I_{D2}, I_{D3} may be set by changing the current threshold/TH.

Next, a step (S150) of detecting defects in the battery cell 10 is performed. For example, if it is determined in step (S140) that it is an abnormal current, it may be determined that the corresponding battery cell 10 is defective. In addition, for example, since the battery cell 10 is divided into a plurality of sub-regions and a current vector value I is derived for each sub-region, the sub-region where an abnormal current is detected can be determined to be a defective region.

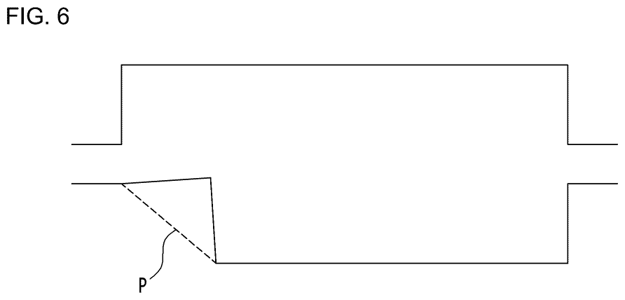

For reference, the defects of the battery cell 10 may include, for example, folding of the electrode plate 11a or disconnection of the electrode plate 11a (e.g., perforation or tearing, etc.), defective application of electrode active material to the coated portion of the electrode plate 11a, disconnection of electrode tabs or electrode leads, or misalignment of a plurality of electrode plates stacked inside the battery cell 10. FIG. 6 shows, as an example, a case where the electrode plate is folded at the folded portion P.

When detecting defects of the battery cell 10 using the apparatus 100 for detecting defects of a battery cell and the method for detecting defects of a battery cell according to the present disclosure, it is possible to quickly determine the presence or absence of defects of the battery cell 10 and/or the coupling portion of the battery cell 10 as compared to the prior art. At the same time, it is possible to more accurately determine the presence or absence of defects of the battery cell 10 and/or the coupling portion of the battery cell 10. Thereby, reliability of the quality of the produced battery cells can be secured.

Although various technical principles have been described in detail above with reference to certain embodiments thereof, it will be appreciated by those skilled in the art that the scope of the present disclosure is not limited thereto, and various modifications and improvements can be made in these embodiments without departing from the principles and sprit of the invention, the scope of which is defined in the appended claims and their equivalents.

### DESCRIPTION OF REFERENCE NUMERALS

10: battery cell
11: main body
12: electrode lead
100: apparatus for detecting defects of a battery cell
110: magnetic field measurement part
111: first measuring member
112: second measuring member
113: third measuring member
120: support section
130: mounting section
131: support member
132: pillar member
133: table
140: processing unit/storage unit

What is claimed is:

1. An apparatus for detecting a defect in a battery cell, comprising:
a magnetic field measuring section;
a support section supporting the magnetic field measuring section; and
a mounting section for placing the battery cell,
wherein the magnetic field measuring section comprises a first measuring member configured to scan a first side of the battery cell, a second measuring member configured to scan a second side of the battery cell opposite to the first side, and a third measuring member is coupled between the first measuring member and the second measuring member, and
wherein the first measuring member, the second measuring member and the third measuring member are connected together.

2. The apparatus of a claim 1, wherein:
the magnetic field measuring section simultaneously scans a top surface, a bottom surface, and a side surface of the battery cell.

3. The apparatus of claim 1, wherein:
the third measuring member connects a first one end of the first measuring member to a first end of the second measuring member.

4. The apparatus of a claim 1, wherein:
the third measuring member is a plurality of third measuring members, wherein a primary measuring member of the plurality of third measuring members connects a first end of the first measuring member to a first end of the second measuring member, and a secondary measuring member of the plurality of third measuring members connects a second end of the first measuring member to a second end of the second measuring member.

5. The apparatus of claim 1, wherein:
the mounting section includes a base and a support member,
wherein the support member has a plate shape for placing the battery cell, and the support member is spaced apart at a prescribed distance upward from the base, and
the second measuring member is disposed below the support member.

6. The apparatus of claim 5, wherein:
the support member has a low magnetic permeability (μ) so that an influence of the support member on magnetic field scanning of the second measuring member is minimized.

7. The apparatus of claim 1,
further comprising a processing unit configured to convert measured magnetic field data to determine the defect in the battery cell or a defective portion of the battery cell.

8. The apparatus of claim 1, wherein:
each of the first measuring member, the second measuring member and the third measuring member has a bar or rod shape, and
the magnetic field measuring section is configured to scan the battery cell by moving in a longitudinal direction of the battery cell.

9. The apparatus of claim 1, wherein:
the first measuring member, the second measuring member and the third measuring member each individually generate a magnetic field data.

10. The apparatus of claim 9, wherein:
a three-dimensional magnetic field vector value is generated from magnetic field data individually generated from each of the first measuring member, the second measuring member, and the third measuring member.

11. The apparatus of claim 9, wherein:
the magnetic field data is a magnetic field image (MFI).

12. The apparatus of claim 1, wherein:
the defect in the battery cell includes at least one of: a folded portion of an electrode plate of the battery cell, a disconnected portion of an electrode plate, an electrode active material is unevenly applied to a coated portion of an electrode plate, a disconnected portion of an electrode lead, a disconnected portion of an electrode tab, or a misalignment of stacked electrode plates.

13. A method for detecting defects of a battery cell, the method comprising the steps of:
receiving magnetic field data measured by a magnetic field measuring section;
deriving a three-dimensional magnetic field vector value for each of a plurality of sub-regions of the battery cell from the received magnetic field data;
converting each of the derived three-dimensional magnetic field vector values into an induced current vector value for a sub-region of the plurality of sub-regions of the battery cell; and
detecting a defect in the battery cell or a defective portion of the battery cell by determining whether a particular induced current vector value for a sub-region of the plurality of sub-regions of the battery cell corresponds to a current value in a normal range by comparing the particular induced current vector value for the sub-region of the plurality of sub-regions of the battery cell with a prescribed current vector threshold.

14. The method of claim 13, wherein:
converting a derived three-dimensional magnetic field vector value into an induced current vector value for a sub-region of the plurality of sub-regions of the battery cell comprises multiplying by a correction coefficient.

15. The method of claim 13, wherein:
determining whether a particular induced current vector value for a sub-region of the plurality of sub-regions of the battery cell corresponds to a current value in a normal range comprises determining if the particular induced current vector value for the sub-region of the plurality of sub-regions of the battery cell is larger than a prescribed upper limit current vector threshold or determining if the particular induced current vector value for the sub-region of the plurality of sub-regions of the battery cell is smaller than a prescribed lower limit current vector threshold.
